(19) United States
(12) Patent Application Publication
(10) Pub. No.: US 2009/0026633 A1
(43) Pub. Date: Jan. 29, 2009

(54) Flip chip package structure and method for manufacturing the same

(75) Inventor: Shih-Ping Hsu, Hsinchu (TW)

Correspondence Address: BACON & THOMAS, PLLC, 625 SLATERS LANE, FOURTH FLOOR, ALEXANDRIA, VA, 22314-1176, US

(73) Assignee: Phoenix Precision Technology Corporation, Hsinchu (TW)

(21) Appl. No.: 12/216,849

(22) Filed: Jul. 11, 2008

(30) Foreign Application Priority Data
Jul. 26, 2007 (TW) 096127326

(51) Int. Cl. H01L 21/60; H01L 23/538

(52) U.S. Cl. 257/778; 438/108; 257/E21.511; 257/E23.169

(57) ABSTRACT

A flip chip package structure and a method for manufacturing the same are disclosed. The method for manufacturing a flip chip package structure comprises following steps: (a) providing a semiconductor chip including a plurality of electrode pads and a plurality of first solders, and providing a packaging substrate having a plurality of conductive pads and a plurality of second solders (b) forming a resin adhesive layer on the active surface of the semiconductor chip, and the first solders are exposed from the resin adhesive layer; (c) assembling the packaging substrate and the semiconductor chip with the resin adhesive layer formed thereon to form an assembly unit; and (d) reflow soldering the assembly unit to fuse the first solders of the semiconductor chip with the second solders of the packaging substrate to form fused solders, and the packaging substrate is adhered with the resin adhesive layer.

### BACKGROUND OF THE INVENTION

1. Field of the Invention

The present invention relates to a flip chip package structure and a method for manufacturing the same and, more particularly to a flip chip package structure with fine pitch and a method for manufacturing the same.

2. Description of Related Art

As the capability for semiconductor processing improves, the development of the semiconductor chip tends to have multifunctions, which leads the structure of the semiconductor chip to become more and more complex. Meanwhile, as the information transferred through the semiconductor chip increases, the number of pins of the semiconductor chip has to be increased.

The conventional wire bonding technique cannot satisfy the demands for the conductivity, due to the development of the semiconductor chip tending to have high frequency and a high number of pins. Comparing to the conventional wire bonding technique, solder bumps are used for the connection between a chip and a substrate in a flip-chip process, wherein the chip faces downward and connects with the substrate through the solder bumps to permit assembly of the flip chip package structure. Additionally, in the semiconductor chip of the flip chip packaging substrate, the I/O pins of the semiconductor chip can be distributed thereon, so that the number of pins can be increased greatly to improve the function of the semiconductor chip, and the pathway for transmitting signals between the semiconductor chip and the substrate can also be shortened. Besides, the interference of noises can be reduced, the ability to diffuse heat can be improved, and the package volume can also be compressed. Hence, the flip-chip technology has become a main trend in the industry.

A conventional process for manufacturing a flip-chip packaging substrate is shown as FIG. 3. A plurality of conductive pads 12 and a solder mask 13 are formed on the packaging substrate 11, and the solder mask 13 has a plurality of openings to expose the conductive pads 12. Also, pre-solders 14 are formed on the conductive pads 12, and the material of the pre-solders 14 is selected from the group consisting of Pb, Sn, Ag, and CU. Furthermore, a plurality of electrode pads 21 and a passivation layer 23 are formed on a chip 20, and the passivation layer 23 has a plurality of openings to expose the electrode pads 21. In addition, solder bumps 25 are formed on the electrode pads 21, as shown in FIG. 3(a).

With reference to FIG. 3(b), a reflow soldering process is performed on the packaging substrate and the chip to fuse solder bumps 25 on the chip and the pre-solders 14 on the packaging substrate and thus form a fused solder 26. Herein, the conductive pads 12 are electrically connected to the electrode pads 21 through the fused solder 26.

After the chip 20 has been soldered with the packaging substrate 11, the space between the chip 20 and the packaging substrate 11 is filled with a under-fill a resin 30, as shown in FIG. 3(c). First, the liquid under-fill resin is deposited in the space between the packaging substrate and the chip. Then, the liquid under-fill resin is cured to fix the positions of the chip and the packaging substrate. Hence, the chip can be secured, and the product reliability can also be improved.

Although the process of depositing under-fill resin can fix the chip and improve the product reliability, the aforementioned conventional process still has its limitations when the pitches of the conductive pads and the electrode pads in the flip chip package structure are fine. With reference to FIG. 3, when the electrode pads 21 and the conductive pads 12 tend to have fine pitches, the volume of the solder bumps 25 has to be reduced. Hence, the gaps between the packaging substrate and the chip have to be reduced. When the gaps between the packaging substrate and the chip are reduced to a certain extent, the process of depositing under-fill resin will become difficult. For example, the under-fill resin cannot fill the space between the packaging substrate and the chip to the full, and voids may be generated between the packaging substrate and the chip. Hence, the phenomenon of popcorn may occur, which will reduce the product reliability. Therefore, the conventional process limits the trend toward manufacturing flip chip package structure with fine pitches. Therefore, it is desirable to provide a flip chip package structure and a method for manufacturing the same to improve the aforementioned problems.

### SUMMARY OF THE INVENTION

The object of the present invention is to provide a method for manufacturing a flip chip package structure, which can reduce the pitches of the flip chip package structure, improve the filling quality of a under-fill resin, and improve the reliability of the flip chip package structure.

Another object of the present invention is to provide a flip chip package structure, which can reduce the pitches of the flip chip package structure.

A further object of the present invention is to provide a flip chip packaging substrate, which can be applied to the flip chip packaging structure with fine pitches.

To achieve the aforementioned objects, the method for manufacturing a flip chip package structure of the present invention comprises the following steps: (a) providing a semiconductor chip including a plurality of electrode pads and a plurality of first solders, and providing a packaging substrate having a plurality of conductive pads and a plurality of second solders; wherein the electrode pads are disposed on an active surface of the semiconductor chip, the first solders are disposed on the electrode pads, the conductive pads are disposed on an upper surface of the packaging substrate, and the second solders are disposed on the conductive pads; (b) forming a resin adhesive layer on the active surface of the semiconductor chip, and the first solders are exposed from the resin adhesive layer; (c) assembling the packaging substrate and the semiconductor chip with the resin adhesive layer formed thereon to form an assembly unit, wherein the first solders of the semiconductor chip correspond to the second solders of the packaging substrate; and (d) reflow soldering the assembly unit to fuse the first solders of the semiconductor chip with the second solders of the packaging substrate to form fused solders, and the packaging substrate is adhered with the resin adhesive layer.

Preferably, according to the method for manufacturing a flip chip package structure, the semiconductor chip in step (a) may further comprise a passivation layer, which comprises a plurality of first openings to expose the electrode pads.

Preferably, according to the method for manufacturing a flip chip package structure, the packaging substrate in the step (a) may further comprise a solder mask formed on the upper surface, and the solder mask comprises a plurality of second openings to expose the conductive pads.

Preferably, according to the method for manufacturing a flip chip package structure, in the step (a), the second solders of the packaging substrate may be solder paste.

Preferably, the method for manufacturing a flip chip package structure may further comprise a step (a1) after step (a): placing a plurality of metal blocks on the second solders of the packaging substrate. According to the aforementioned method, the shapes of the metal blocks are unlimited. Preferably, the metal blocks are ball-shaped metal blocks or ellipse-shaped metal blocks.

Preferably, the method for manufacturing a flip chip package structure may further comprise a step (a2) after the step (a): forming a plurality of pre-solders on the second solders of the packaging substrate. According to the aforementioned method, the pre-solders may further comprise a flux.

Preferably, according to the method for manufacturing a flip chip package structure, the first solders in the step (a) have a height of 10-50 μm.

Preferably, according to the method for manufacturing a flip chip package structure, in step (b), the thickness of the resin adhesive layer is less than the height of the first solders. More preferably, the first solders are exposed from the resin adhesive layer.

Preferably, the method for manufacturing a flip chip package structure may further comprise a step (b1) after step (b): drying the resin adhesive layer formed on the semiconductor chip.

According to the method for manufacturing a flip chip package structure, the material of the first solders is selected from the group consisting of Pb, Sn, Zn, Bi, Au, Ag, Cu, and an alloy thereof.

According to the method for manufacturing a flip chip package structure, the material of the second solders is selected from the group consisting of Pb, Sn, Zn, Bi, Au, Ag, Cu, and an alloy thereof.

In addition, the flip chip package structure of the present invention comprises: (a) a flip chip packaging chip, which comprises: an active surface, and a plurality of electrode pads formed on the active surface; and a resin adhesive layer disposed on the active surface of the flip chip packaging chip; and (b) a flip chip packaging substrate, which comprises: an upper surface, and a plurality conductive pads formed on the upper surface; and a solder mask formed on the upper surface, and the solder mask comprising a plurality of openings to expose the conductive pads. In the aforementioned flip chip package structure, the resin adhesive layer of the flip chip packaging chip adheres with the solder mask of the flip chip packaging substrate to form a flip chip package structure, and the electrode pads of the flip chip packaging chip are electrically connected to the conductive pads of the flip chip packaging substrate through a fused solder.

Preferably, the flip chip package structure of the present invention may further comprise a metal block wrapped in the fused solder. According to the aforementioned flip chip package structure, the shape of the metal block is unlimited. Preferably, the metal block is a ball-shaped metal block or an ellipse-shaped metal block.

Preferably, in the flip chip package structure of the present invention, the conductive pads may be copper pads.

Preferably, in the flip chip package structure of the present invention, the electrode pads may be aluminum pads or copper pads.

In the flip chip package structure of the present invention, the material of the fused solder is selected from the group consisting of Pb, Sn, Zn, Bi, Au, Ag, Cu, and an alloy thereof.

In the flip chip package structure of the present invention, the metal block is a ball-shaped metal block or an ellipse-shaped metal block.

In the flip chip package structure of the present invention, the second solders are solder paste.

Furthermore, the flip chip package structure of the present invention comprises: an upper surface, and a plurality of conductive pads formed thereon; a solder mask formed on the upper surface, wherein the solder mask comprising a plurality of openings to expose the conductive pads; a plurality of second solders disposed on the conductive pads; and a plurality of paste-shaped pre-solders disposed on the second solders.

Other objects, advantages, and novel features of the invention will become more apparent from the following detailed description when taken in conjunction with the accompanying drawings.

### BRIEF DESCRIPTION OF THE DRAWINGS

FIG. 1 is a cross-sectional view for illustrating a process for manufacturing a flip chip package structure according to embodiment 1 of the present invention;

FIG. 2 is a cross-sectional view for illustrating a process for manufacturing a flip chip package structure according to embodiment 2 of the present invention; and

FIG. 3 is a cross-sectional view for illustrating a process for manufacturing a conventional flip chip package structure.

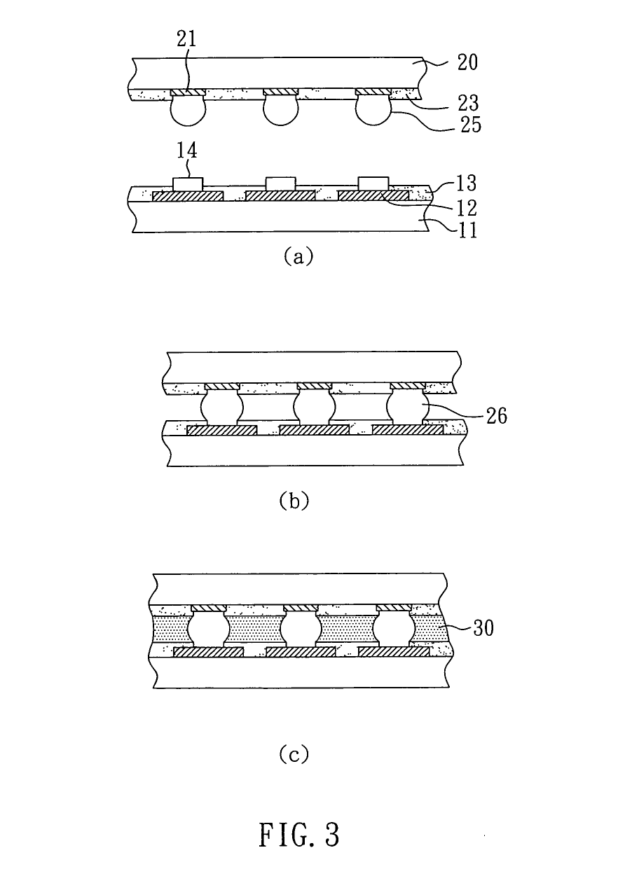

### DETAILED DESCRIPTION OF THE PREFERRED EMBODIMENT

Because of the specific embodiments illustrating the practice of the present invention, a person having ordinary skill in the art can easily understand other advantages and efficiency of the present invention through the content disclosed therein. The present invention can also be practiced or applied by other variant embodiments. Many other possible modifications and variations of any detail in the present specification based on different outlooks and applications can be made without departing from the spirit of the invention.

The figures in the embodiments of the present invention are simplified perspective views. Only the elements related to the present invention are shown in these figures, and these figures do not illustrate the practical aspects. The numbers and shapes of the elements are designed according to the practical situations. Hence, the arrangement of the elements may be more complex in practice.

### Embodiment 1

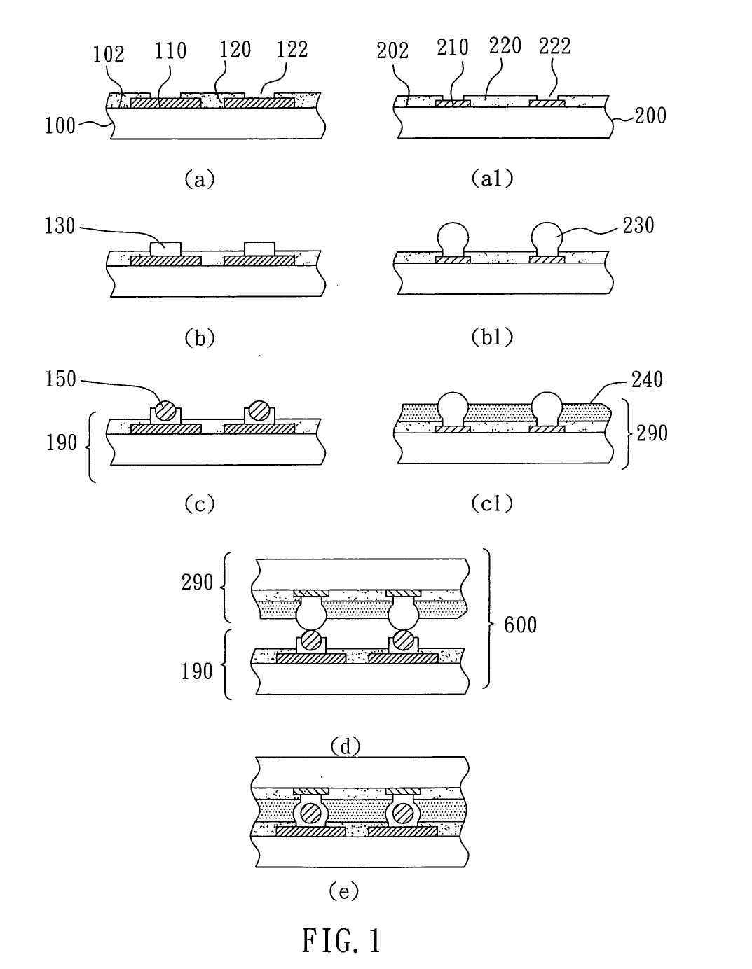

FIG. 1 shows the process for manufacturing a flip chip package structure of the present embodiment. First, a packaging substrate 100 and a semiconductor chip 200 are provided. A plurality of conductive pads 110 and a solder mask 120 are formed on an upper surface 102 of the packaging substrate 100, and the solder mask 120 has a plurality of second openings 122 to expose the conductive pads 110. A plurality of electrode pads 210 and a passivation layer 220 are formed on an active surface 202 of the semiconductor chip 220, and the passivation layer 220 has a plurality of first openings 222 to expose the electrode pads 210. FIG. 1(a) and FIG. 1(a1) show the cross-sectional views of the packaging substrate and the semiconductor chip.

Then, as shown in FIG. 1(b) and FIG. 1(b1), a plurality of first solders 230 is formed on the semiconductor chip 200, and the first solders 230 are disposed on the electrode pads 210. In the present invention, the material of the first solders can be selected from the group consisting of Pb, Sn, Zn, Bi, Au, Ag, Cu, and an alloy thereof. Besides, the first solders can be formed by conventional screen printing or electroplating. In addition, a plurality of second solders 130 is formed on the conductive pads 110 of the packaging substrate 100. The material of the second solders 130 can be selected from the group consisting of Pb, Sn, Zn, Bi, Au, Ag, Cu, and an alloy thereof. In the present embodiment, the second solders 130 can be solder paste, which can be formed by screen printing or electroplating.

With reference to FIG. 1(c), a plurality of metal blocks 150 is respectively placed on the second solders 130 of the packaging substrate 100 to form a flip chip packaging substrate, wherein the metal blocks 150 placed on the second solders 130 can provide suitable height that is easily contact with chip. In the present embodiment, each second solder 130 is set with a metal block 150, and the particle size of the metal block 150 is less than the width of the second solder 130. Preferably, the metal blocks 150 are ball-shaped metal blocks. Furthermore, in the present embodiment, the second solders 130 are solder paste, so that the metal blocks 150 can adhere on the second solders 130 easily.

Then, a resin adhesive layer 240 is such as a polymer resin formed on the semiconductor chip 200. After curing of the resin adhesive layer 240, the resin adhesive layer 240 is half-dry and viscous, and a flip chip packaging chip 290 is formed. The resin adhesive layer 240 can be formed by spin coating or screen printing. In the present embodiment, the thickness of the resin adhesive layer 240 is less than the height of the first solders 230 formed on the semiconductor chip 220 to expose the top of the first solders 230, as shown in FIG. 1(c1). The process of drying can be performed by vacuum drying or heating to move parts of solvent inside the resin adhesive layer. Besides, the resin adhesive layer 240 can be set on the semiconductor chip 220.

With reference to FIG. 1(d), the flip chip packaging chip 290 assembles with and corresponds to the flip chip packaging substrate 190 to form an assembly unit 600. During the process of assembling the flip chip packaging chip 290 and the flip chip packaging substrate 190, the active surface 202 of the flip chip packaging chip 290 faces to the upper surface 102 of the flip chip packaging substrate 190. In addition, the first solders 230 formed on the semiconductor chip correspond to the second solders 230 formed on the substrate respectively.

With reference to FIG. 1(e), a process of heating and reflow soldering is performed on the assembly unit 600 to fuse the first solders 230 of the flip chip packaging chip with the second solders 130 of the flip chip packaging substrate 190. During the process of heating and reflow soldering, the first solders 230 and the second solders 130 transfer to a fused state. Hence, the first solders 230 and the second solders 130 can be melted and blended with each other to form a fused solder 330. Additionally, the metal blocks 150 are wrapped in the fused solder 330. The fused solder 330, as a conductive medium, can electrically connect the electrode pads 210 with the conductive pads 110.

Meanwhile, during the process of heating and reflow soldering, the resin adhesive layer 240 of the flip chip packaging chip 290 is also under high temperature, so that the resin adhesive layer 240 can adhere with the solder mask 120 of the flip chip packaging substrate 190. Besides, the resin adhesive layer 240 can fill the space between the flip chip packaging chip 290 and the flip chip packaging substrate 190. In addition, during the process of heating and reflow soldering, a heavy component may be selectively placed on the semiconductor chip. The heavy component can apply suitable stress on the semiconductor chip to ensure the resin adhesive layer 240 contacts and adheres with flip chip packaging substrate 190 completely. After the process of reflow soldering has been completed, the resin adhesive layer 240 is adhered with the flip chip packaging chip 290 and the flip chip packaging substrate 190. Finally, the flip chip package structure of the present embodiment is formed.

In the present embodiment, the resin adhesive layer 240 is formed on the semiconductor chip in advance, and the resin adhesive layer 240 can adhere with the substrate through the process of heating and reflow soldering. Hence, during the process for manufacturing the flip chip package structure of the present embodiment, a step of depositing under-fill resin can be omitted. Therefore, the problem that the under-fill resin cannot fill the space between the semiconductor chip and the substrate to the full when the flip chip package structure has fine pitches, can be diminished.

In the conventional process of depositing under-fill resin, when the height of the first solders 230 is less than 80 μm, the condition of poor filling may occur easily. In the present embodiment, a process wherein a resin adhesive layer 240 is formed on the semiconductor chip 200 in advance, can replace the conventional process of depositing under-fill resin. Hence, the flip chip package structure of the present invention and the method for manufacturing the same can be applied to the flip chip package structure, in which the height of the first solders 230 of the semiconductor chip 200 is 10˜50 μm. Therefore, the method disclosed in the present embodiment can greatly improve the ability to make the flip chip package structure with fine pitches. Additionally, the method disclosed in the present embodiment can provide products with good reliability at the same time.

### Embodiment 2

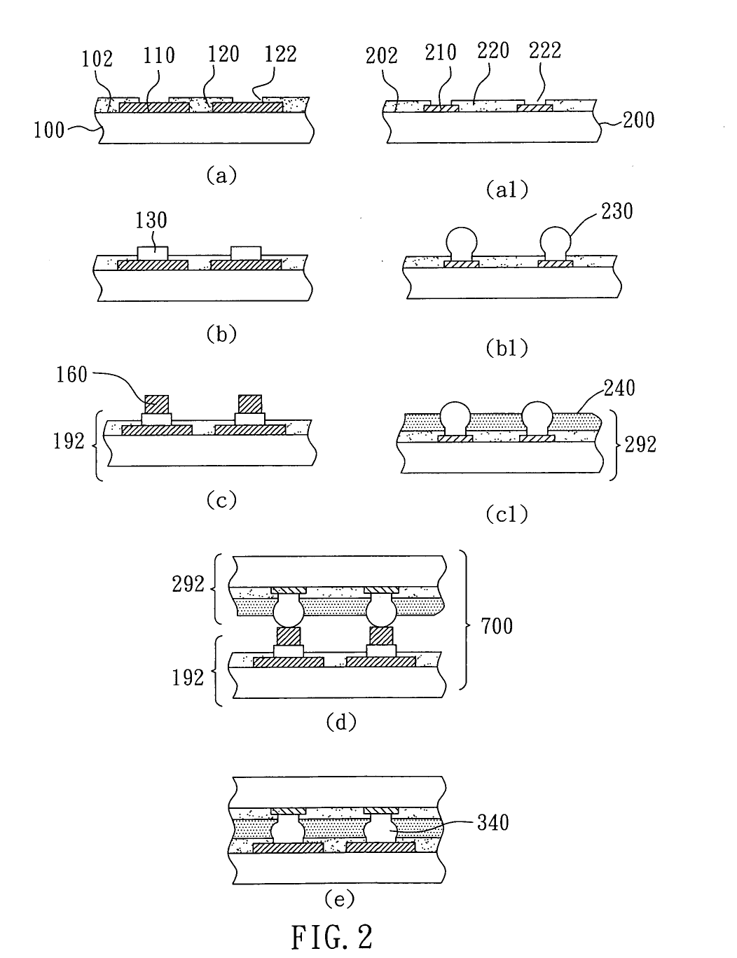

FIG. 2 shows the process for manufacturing a flip chip package structure of the present embodiment. First, a packaging substrate 100 and a semiconductor chip 200 are provided. A plurality of conductive pads 110 and a solder mask 120 are formed on an upper surface 102 of the packaging substrate 100, and the solder mask 120 has a plurality of second openings 122 to expose the conductive pads 110. A plurality of electrode pads 210 and a passivation layer 220 are formed on an active surface 202 of the semiconductor chip 220, and the passivation layer 220 has a plurality of first openings 222 to expose the electrode pads 210. FIG. 2(a) and FIG. 2(a1) show the cross-sectional views of the packaging substrate and the semiconductor chip.

Then, as shown in FIG. 2(b) and FIG. 2(b1), a plurality of first solders 230 is formed on the semiconductor chip 200, and the first solders 230 are disposed on the electrode pads and correspond to the electrode pads 210. In the present invention, the material of the first solders can be selected from the group consisting of Pb, Sn, Zn, Bi, Au, Ag, Cu, and an alloy thereof. Besides, the first solders can be formed by conventional screen printing or electroplating. In addition, a plurality of second solders 130 is formed on the conductive pads 110 of the packaging substrate 100. In the present embodiment, the material of the second solders 130 can be selected from the group consisting of Pb, Sn, Zn, Bi, Au, Ag, Cu, and an alloy thereof. Besides, the second solders 130 can be formed by screen printing or electroplating.

With reference to FIG. 2(c), a plurality of pre-solders 160 is respectively formed on the second solders 130 of the packaging substrate 100 to obtain a flip chip packaging substrate 192, wherein the pre-solders 160 placed on the second solders 130 can provide suitable height that is easily contact with chip. In the present embodiment, the pre-solders 160 are paste-shaped pre-solders which comprise a flux, and the width of the pre-solders 160 is less than the width of the second solders 130. Besides, the pre-solders 160 can be formed by conventional screen printing or coating.

Then, a resin adhesive layer 240 is formed on the semiconductor chip 200. After curing of the resin adhesive layer 240, the resin adhesive layer 240 is half-dry and viscous, and a flip chip packaging chip 292 is formed. The resin adhesive layer 240 can be formed by spin coating or screen printing. In the present embodiment, the thickness of the resin adhesive layer 240 is less than the height of the first solders 230 formed on the semiconductor chip 220 to expose the top of the first solders 230, as shown in FIG. 2(d). The process of drying can be performed by vacuum drying or heating to move parts of solvent inside the resin adhesive layer. Besides, the resin adhesive layer 240 can be set on the semiconductor chip 220.

With reference to FIG. 2(d), the flip chip packaging chip 292 assembles with and corresponds to the flip chip packaging substrate 192 to form an assembly unit 700. During the process of assembling the flip chip packaging chip 292 and the flip chip packaging substrate 192, the active surface 202 of the flip chip packaging chip 292 faces to the upper surface 102 of the flip chip packaging substrate 192. In addition, the first solders 230 formed on the flip chip packaging chip 292 correspond to the second solders 130 formed on the flip chip packaging substrate 192 respectively.

With reference to FIG. 2(e), a process of heating and reflow soldering is performed on the assembly unit 700 to fuse the first solders 230 of the flip chip packaging chip 292 with the second solders 130 of the flip chip packaging substrate 192. In the present embodiment, the pre-solders 160 are paste-shaped solders which comprises a flux. Hence, during the process of heating and reflow soldering, the flux inside the pre-solders 160 can vaporize into gas, so that the first solders 230, the pre-solders 160 and the second solders 130 can be melted and blended with each other to form fused solders 340. Herein, the fused solder 340, as a conductive medium, can electrically connect the electrode pads 210 with the conductive pads 110.

Meanwhile, during the process of heating and reflow soldering, the resin adhesive layer 240 of the flip chip packaging chip 292 is also under high temperature, so that the resin adhesive layer 240 can adhere with the solder mask 120 of the flip chip packaging substrate 192. Besides, the resin adhesive layer 240 can fill the space between the flip chip packaging chip 292 and the flip chip packaging substrate 192. In addition, during the process of heating and reflow soldering, a heavy component may be selectively placed on the semiconductor chip. The heavy component can apply suitable stress on the semiconductor chip to ensure the resin adhesive layer 240 contacts and adheres with flip chip packaging substrate 192 completely. After the process of reflow soldering has been completed, the resin adhesive layer 240 is adhered with the flip chip packaging chip 292 and the flip chip packaging substrate 192. Finally, the flip chip package structure of the present embodiment is formed.

In the present embodiment, the resin adhesive layer 240 is formed on the semiconductor chip in advance, and the resin adhesive layer 240 can adhere with the substrate through the process of heating and reflow soldering. Hence, during the process for manufacturing the flip chip package structure of the present embodiment, a step of depositing under-fill resin can be omitted. Therefore, the problem that under-fill resin cannot fill the space between the semiconductor chip and the substrate to the full when the flip chip package structure has fine pitches can be diminished.

In the conventional process of depositing under-fill resin, when the height of the first solders 230 is less than 80 μm, the condition of poor filling may occur easily. In the present embodiment, a process wherein a resin adhesive layer is formed on the semiconductor chip in advance can replace the conventional process of depositing under-fill resin. Hence, the flip chip package structure of the present invention and the method for manufacturing the same can be applied to the flip chip package structure, in which the height of the first solders 230 of the semiconductor chip 200 is 10˜50 μm. Therefore, the method disclosed in the present embodiment can greatly improve the ability to make the flip chip package structure with fine pitches. Additionally, the method disclosed in the present embodiment can provide products with good reliability at the same time.

Although the present invention has been explained in relation to its preferred embodiment, it is to be understood that many other possible modifications and variations can be made without departing from the scope of the invention as hereinafter claimed.

What is claimed is:

1. A method for manufacturing a flip chip package structure, comprising following steps:
(a) providing a semiconductor chip comprising a plurality of electrode pads and a plurality of first solders, and providing a packaging substrate having a plurality of conductive pads and a plurality of second solders; wherein the electrode pads are disposed on an active surface of the semiconductor chip, the first solders are disposed on the electrode pads, the conductive pads are disposed on an upper surface of the packaging substrate, and the second solders are disposed on the conductive pads;
(b) forming a resin adhesive layer on the active surface of the semiconductor chip, and the first solders are exposed from the resin adhesive layer;
(c) assembling the packaging substrate and the semiconductor chip with the resin adhesive layer formed thereon to form an assembly unit, wherein the first solders of the semiconductor chip correspond to the second solders of the packaging substrate; and
(d) reflow soldering the assembly unit to fuse the first solders of the semiconductor chip with the second solders of the packaging substrate to form fused solders, and the packaging substrate is adhered with the resin adhesive layer.

2. The method as claimed in claim 1, wherein the semiconductor chip in the step (a) further comprising a passivation layer, which comprises a plurality of first openings to expose the electrode pads.

3. The method as claimed in claim 1, wherein the packaging substrate in the step (a) further comprising a solder mask formed on the upper surface, and the solder mask comprises a plurality of second openings to expose the conductive pads.

4. The method as claimed in claim 1, wherein in the step (a), the second solders of the packaging substrate are solder paste.

5. The method as claimed in claim 1, further comprising a step (a1) after the step (a): placing a plurality of metal blocks on the second solders of the packaging substrate.

6. The method as claimed in claim 5, wherein the metal blocks are ball-shaped metal blocks.

7. The method as claimed in claim 1, further comprising a step (a2) after the step (a): forming a plurality of pre-solders on the second solders of the packaging substrate.

8. The method as claimed in claim 7, wherein the pre-solders further comprise a flux.

9. The method as claimed in claim 1, wherein the first solders in the step (a) have a height of 10-50 μm.

10. The method as claimed in claim 1, wherein in the step (b), the thickness of the resin adhesive layer is less than the height of the first solders to expose the first solders.

11. The method as claimed in claim 1, further comprising a step (b1) after the step (b): drying the resin adhesive layer formed on the semiconductor chip.

12. The method as claimed in claim 1, wherein the material of the first solders is selected from the group consisting of Pb, Sn, Zn, Bi, Au, Ag, Cu, and an alloy thereof.

13. The method as claimed in claim 1, wherein the material of the second solders is selected from the group consisting of Pb, Sn, Zn, Bi, Au, Ag, Cu, and an alloy thereof.

14. A flip chip package structure, comprising:
(a) a flip chip packaging chip, which comprises:
an active surface, and a plurality of electrode pads formed on the active surface; and
a resin adhesive layer disposed on the active surface of the flip chip packaging chip; and
(b) a flip chip packaging substrate, which comprises:
an upper surface, and a plurality conductive pads formed on the upper surface; and
a solder mask formed on the upper surface, and the solder mask comprising a plurality of openings to expose the conductive pads;
wherein, the resin adhesive layer of the flip chip packaging chip adheres with the solder mask of the flip chip packaging substrate to form a flip chip package structure, and the electrode pads of the flip chip packaging chip are respectively electrically connected to the conductive pads of the flip chip packaging substrate through a fused solder.

15. The flip chip package structure as claimed in claim 14, further comprising a metal block wrapped in the fused solder.

16. The flip chip package structure as claimed in claim 15, wherein the metal block is a ball-shaped metal block or an ellipse-shaped metal block.

17. The flip chip package structure as claimed in claim 14, wherein the conductive pads are copper pads.

18. The flip chip package structure as claimed in claim 14, wherein the electrode pads are aluminum pads or copper pads.

19. The flip chip package structure as claimed in claim 14, wherein the material of the fused solder is selected from the group consisting of Pb, Sn, Zn, Bi, Au, Ag, Cu, and an alloy thereof.

20. A flip chip packaging substrate, comprising:
an upper surface, and a plurality of conductive pads formed thereon;
a solder mask formed on the upper surface, wherein the solder mask comprising a plurality of openings to expose the conductive pads;
a plurality of second solders disposed on the conductive pads; and
a plurality of metal blocks disposed on the second solders.

21. The flip chip packaging substrate as claimed in claim 20, wherein the metal block is a ball-shaped metal block or an ellipse-shaped metal block.

22. The flip chip packaging substrate as claimed in claim 20, wherein the second solders of the packaging substrate are solder paste.

23. A flip chip packaging substrate, comprising:
an upper surface, and a plurality of conductive pads formed thereon;
a solder mask formed on the upper surface, wherein the solder mask comprising a plurality of openings to expose the conductive pads;
a plurality of second solders disposed on the conductive pads; and
a plurality of paste-shaped pre-solders disposed on the second solders.
